(19) United States
(12) Patent Application Publication
(10) Pub. No.: US 2026/0070161 A1
(43) Pub. Date: Mar. 12, 2026

(54) PROFILED SOLDER RIBBON

(71) Applicant: SUZHOU MAXWELL TECHNOLOGIES CO., LTD., Suzhou (CN)

(72) Inventors: Weijia YAN, Suzhou (CN); Jing ZHENG, Suzhou (CN); Jianming YAN, Suzhou (CN); Wei LI, Suzhou (CN)

(73) Assignee: SUZHOU MAXWELL TECHNOLOGIES CO., LTD., Suzhou (CN)

(21) Appl. No.: 19/273,065

(22) Filed: Jul. 17, 2025

(30) Foreign Application Priority Data
Sep. 6, 2024 (CN) 202422184121.8
Dec. 25, 2024 (CN) 202423210159.4

(51) Int. Cl. B23K 35/02; H10F 77/00

(52) U.S. Cl. CPC B23K 35/0227; H10F 77/937

(57) ABSTRACT

Provided in the present disclosure is a profiled solder ribbon, which relates to the technical field of solar cell manufacturing. The profiled solder ribbon according to the present disclosure includes a plurality of solder ribbon units connected in sequence, and each solder ribbon unit includes a profiled segment, a first transition segment, a flat segment, and a second transition segment connected in sequence. The section of the profiled segment is in the shape formed by superimposing the triangle with the rectangle, so that light, when shining on an area of the triangle, can be reflected to a solar cell by the triangle to increase the light utilization. In addition, a lower part of a section of the profiled solder ribbon according to the present disclosure is rectangular, which can share part of the copper consumption required for electrical conduction, reduce the shielding of cells, and improve the light utilization.

### CROSS-REFERENCE TO RELATED APPLICATIONS

This application claims priority to Chinese Patent Application No. 202422184121.8, filed on Sep. 6, 2024 and Chinese Patent Application No. 202423210159.4, filed on Dec. 25, 2024, the contents of each of which are hereby incorporated by reference.

### TECHNICAL FIELD

The present disclosure relates to the technical field of solar cell manufacturing, in particular to a profiled solder ribbon.

### BACKGROUND OF THE INVENTION

After being manufactured, multiple solar cells need to be mutually soldered together to form a cell string. Generally, multiple cells are soldered to one another by using solder ribbons. To ensure the performance of cells, profiled solder ribbons are generally used for soldering. Under the condition of the same electrical conductivity, circular solder ribbons in existing profiled solder ribbons have a greater shielding effect on cells, thus affecting the power generation performance of the cells. Additionally, there are no transition segments at joints between profiled segments and flat segments in some profiled solder ribbons. If the profiled segments are located on edges of cells, the cells are prone to fragmentation during lamination.

### SUMMARY

An objective of a first aspect of the present disclosure is to provide a profiled solder ribbon, which solves the problem in the prior art that the shielding effect of the profiled solder ribbon is great and does not contribute to the power generation performance.

Particularly, the present disclosure provides a profiled solder ribbon, including a plurality of solder ribbon units connected in sequence, each of the solder ribbon units including a profiled segment, a first transition segment, a flat segment, and a second transition segment connected in sequence, where a section of the profiled segment is in a shape formed by superimposing a triangle above with a rectangle below, and a section of the flat segment is in a shape of a rectangle.

Optionally, the profiled segment includes an internal copper core and an external plating, and the internal copper core includes a triangular portion located above and a rectangular portion located below, where an angle of a top corner of the triangular portion is less than 90°.

Optionally, the top corner of the triangular portion is an arc with a radian of π/36 to 5π/9.

Optionally, two side surfaces of the triangular portion are planes, and the external plating includes a first plating disposed outside the two side surfaces of the triangular portion; and the reflectivity of the first plating is 70-100%.

Optionally, a material of the first plating is selected from one or more of aluminum, aluminum alloy, silver, silver alloy, tin, and lead.

Optionally, the thickness of the first plating is 1-6 μm.

Optionally, two side surfaces of the triangular portion of the internal copper core are formed into concave surfaces inwards; and the external plating includes a second plating disposed outside the concave surfaces and made of tin or tin alloy.

Optionally, the thickness of the second plating is 8-15 μm.

Optionally, the rectangle of the profiled segment has the same shape and size as the section of the flat segment, and for the rectangle of the profiled segment and the rectangle of the section of the flat segment, a corner between a bottom and each side is rounded.

Optionally, a height of the first transition segment and a height of the second transition segment gradually decrease from the profiled segment to the flat segment.

Optionally, a section of the first transition segment and a section of the second transition segment are each in a shape formed by an isosceles trapezoid located above and a rectangle located below.

Optionally, two legs of the isosceles trapezoid are both recessed inwards.

Optionally, a thickness of the external plating is 15 μm±3 μm.

The section of the profiled segment in this solution is in the shape formed by superimposing the triangle with the rectangle, so that light, when shining on an area of the triangle, can be completely reflected to a solar cell by the triangle to increase the light utilization. In addition, a lower part of a section of the profiled solder ribbon in this solution is rectangular, which can share part of the copper consumption required for electrical conduction, reduce the shielding of cells, and improve the light utilization.

In this solution, for the rectangle of the profiled segment and the rectangle of the section of the flat segment, the corner between the bottom and each side is rounded, which can avoid cutting injury during operation. Furthermore, compared with right angles, rounded angles have a more attractive appearance.

The top corner of the triangular portion of the internal copper core in the profiled segment in this solution is the arc, which can avoid the occurrence of a sharp portion on an outer layer and stress concentration on the sharp portion, prevent damage to the outer layer and the plating, and protect the solder ribbon and an operator.

Based on the detailed description of specific embodiments of the present disclosure with reference to the accompanying drawings, those skilled in the art will have a better understanding of the above and other objectives, advantages, and features of the present disclosure.

### BRIEF DESCRIPTION OF THE DRAWINGS

Some specific embodiments of the present disclosure will be described in detail by way of example rather than limitation below with reference to the accompanying drawings. The same reference signs in the accompanying drawings indicate the same or similar components or parts. It should be understood by those skilled in the art that these drawings are not necessarily drawn to scale. In the drawings:

FIG. 1 is a partial front view of a profiled solder ribbon according to a specific embodiment of the present disclosure;

FIG. 2 is a partial schematic perspective view of a profiled solder ribbon according to a specific embodiment of the present disclosure;

FIG. 3 is a schematic sectional view of a profiled segment according to a specific embodiment of the present disclosure;

FIG. 4 is a schematic sectional view of a profiled segment according to another specific embodiment of the present disclosure;

FIG. 5 is a schematic sectional view of a first transition segment or a second transition segment according to a specific embodiment of the present disclosure; and

FIG. 6 is a schematic sectional view of a first transition segment or a second transition segment according to a specific embodiment of the present disclosure.

### DESCRIPTION OF REFERENCE SIGNS

profiled solder ribbon—100; profiled segment—110; triangle—111; rectangle—112; internal copper core—113; first plating—114; triangular portion—115; rectangular portion—116; top corner—117; second plating—118; first transition segment—120; flat segment—130; and second transition segment—140.

### DETAILED DESCRIPTION OF THE INVENTION

In the description of this embodiment, it is to be understood that the orientations or positional relationships indicated by the terms “length”, “width”, “height”, “up”, “down”, “left”, “right”, “vertical”, “horizontal”, “bottom”, “inside”, “outside”, etc. are based on the orientations or positional relationships shown in the accompanying drawings, merely for conveniently describing the present disclosure and simplifying the description, rather than indicating or implying that the apparatus or element referred to must have a particular orientation or be constructed and operated in a particular orientation, and therefore cannot be understood as limitations to the present disclosure.

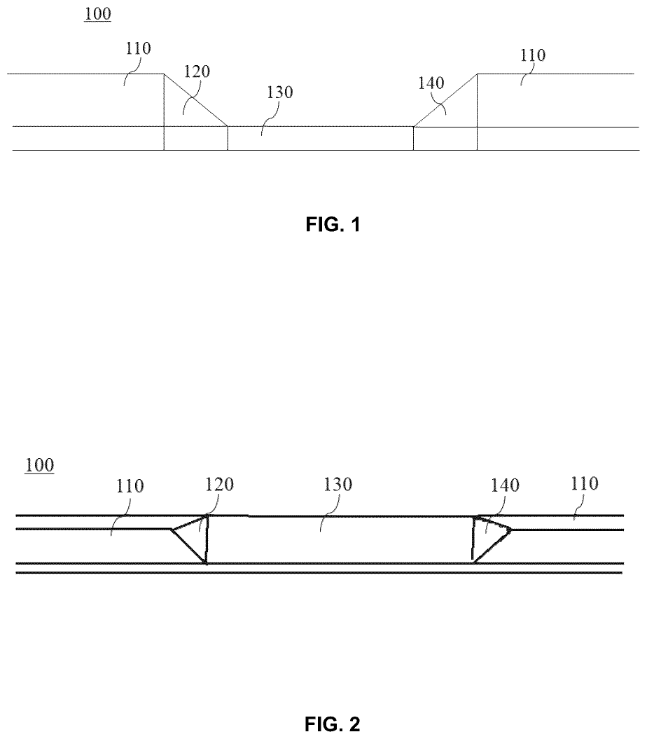

As a specific embodiment of the present disclosure, as shown in FIG. 1 and FIG. 2, this embodiment provides a profiled solder ribbon 100. The profiled solder ribbon 100 includes a plurality of solder ribbon units connected in sequence, and each solder ribbon unit may include a profiled segment 110, a first transition segment 120, a flat segment 130, and a second transition segment 140 connected in sequence, where a section of the profiled segment 110 is in a shape formed by superimposing a triangle 111 above with a rectangle 112 below, and a section of the flat segment 130 is in a shape of a rectangle.

Specifically, the section of the profiled segment 110 in this embodiment is in the shape formed by superimposing the triangle 111 with the rectangle 112, so that light, when shining on an area of the triangle 111, can be completely reflected to a solar cell by the triangle 111 to increase the light utilization. In addition, a lower part of a section of the profiled solder ribbon 100 in this embodiment is rectangular, which can share part of the copper consumption required for electrical conduction, reduce the shielding of cells, and improve the light utilization.

As a specific embodiment of the present disclosure, the rectangle 112 of the profiled segment 110 has the same shape and size as the section of the flat segment 130. For the rectangle 112 of the profiled segment 110 and the rectangle of the section of the flat segment 130, a corner between a bottom and each side is rounded.

Specifically, in this embodiment, the rectangle 112 of the profiled segment 110 has the same shape and size as the section of the flat segment 130, so that only the triangle 111 gradually disappears during gradual transition of the transition segments from the profiled segment 110 to the flat segment 130. For the rectangle 112 of the profiled segment 110 and the rectangle of the section of the flat segment 130, the corner between the bottom and each side is rounded, which can avoid cutting injury during operation. Furthermore, compared with right angles, rounded angles have a more attractive appearance.

Specifically, a height of the first transition segment 120 and a height of the second transition segment 140 in this embodiment gradually decrease from the profiled segment 110 to the flat segment 130. The arrangement of the transition segments can decrease and balance a height difference between the profiled segment 110 and the flat segment 130, and reduce fragments during lamination.

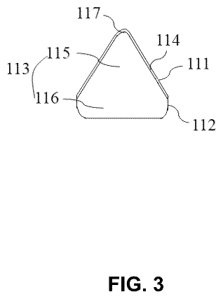

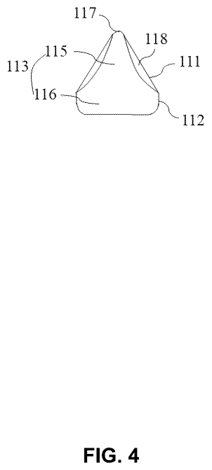

As a specific embodiment of the present disclosure, as shown in FIG. 3 and FIG. 4, the profiled segment 110 in this embodiment may include an internal copper core 113 and an external plating.

Specifically, the internal copper core 113 of the profiled segment 110 includes a triangular portion 115 located above and a rectangular portion 116 located below, where an angle of a top corner 117 of the triangular portion 115 is less than 90°. For example, the angle of the top corner 117 of the triangular portion 115 in this embodiment may be 90°, 60°, 45°, 30°, etc.

Preferably, the angle of the top corner 117 of the triangular portion 115 in this embodiment is 60°.

As a specific embodiment of the present disclosure, the top corner 117 of the triangular portion 115 is an arc with a radian of π/36 to 5π/9. For example, the radian of the arc of the top corner in this embodiment is π/36, π5/36, 5π/9, etc.

Specifically, the top corner 117 of the triangular portion 115 of the internal copper core 113 in the profiled segment 110 in this embodiment is the arc, which can avoid the occurrence of a sharp portion on an outer layer and stress concentration on the sharp portion, prevent damage to the outer layer and the plating, and protect the solder ribbon and an operator.

As a specific embodiment of the present disclosure, as shown in FIG. 3, two side surfaces of the triangular portion 115 of the internal copper core 113 in this embodiment are planes. In this case, the external plating may be a first plating 114. The first plating 114 is disposed outside the two side surfaces of the triangular portion 115, and the reflectivity of the first plating 114 is 70-100%. For example, the reflectivity of the first plating 114 may be 70%, 80%, 90%, or 100%. Specifically, the reflectivity of the first plating 114 can be selected based on actual requirements. The first plating 114 with such a high reflectivity is disposed on the two side surfaces of the triangular portion 115, so that the light utilization can be improved without affecting the shape of the profiled solder ribbon, thus bringing gains to the power of a module.

Specifically, a material of the first plating 114 can be selected from one or more of aluminum, aluminum alloy, silver, silver alloy, tin, and lead. These materials have a relatively high reflectivity, which can improve the light utilization and bring gains to the power of a final device.

Specifically, the first plating 114 in this embodiment can be obtained by means of electroplating.

Specifically, the thickness of the first plating 114 may be 1-6 μm, such as 1 μm, 3 μm, 5 μm, or 6 μm. The specific thickness of the first plating 114 can be designed based on the actual situation.

As a specific embodiment of the present disclosure, as shown in FIG. 4, two side surfaces of the triangular portion 115 of the internal copper core 113 are recessed inwards to form concave surfaces. The external plating in this embodiment may include a second plating 118. The second plating 118 can be filled in a recessed part to make an outer surface flat, so that the overall shape of the profiled solder ribbon 100 after plating can better fit with the shape of the internal copper core 113, and the front and back of the profiled solder ribbon 100 can be conveniently distinguished.

Specifically, the second plating 118 can be made of tin or tin alloy, and can also be obtained by means of electroplating. In addition, the thickness of the second plating 118 may be 8-15 μm, for example, the thickness of the second plating 118 may be 8 μm, 10 μm, 12 μm, or 15 μm. The specific thickness of the second plating 118 can be designed based on the actual situation.

Specifically, a section of the first transition segment 120 and a section of the second transition segment 140 are each in a shape formed by an isosceles trapezoid located above and a rectangle located below.

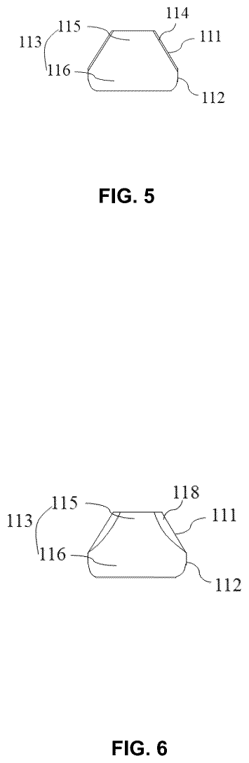

When the two side surfaces of the triangular portion 115 are of a planar structure, two legs of the isosceles trapezoid of the inner copper core are also of the planar structure (as shown in FIG. 5). When the two side surfaces of the triangular portion 115 are inwards-recessed concave surfaces, the two legs of the isosceles trapezoid of the inner copper core are also the inwards-recessed concave surfaces (as shown in FIG. 6).

Specifically, both the first transition segment 120 and the second transition segment 140 in this embodiment transit from the profiled segment 110 to the flat segment 130, and the transition segments have similar sides to the profiled segment, thereby ensuring that the outer plated surface is flat.

By now, it should be recognized by those skilled in the art that while the multiple exemplary embodiments of the present disclosure have been shown and described in detail herein, many other variations or modifications conforming to the principle of the present disclosure may still be directly determined or derived from the content of the present disclosure without departing from the spirit and scope of the present disclosure. Therefore, the scope of the present disclosure should be understood and recognized as covering all such other variations or modifications.

What is claimed is:

1. A profiled solder ribbon, comprising a plurality of solder ribbon units connected in sequence, each of the solder ribbon units comprising a profiled segment, a first transition segment, a flat segment, and a second transition segment connected in sequence, wherein a section of the profiled segment is in a shape formed by superimposing a triangle above with a rectangle below, and a section of the flat segment is in a shape of a rectangle.

2. The profiled solder ribbon according to claim 1, wherein
the profiled segment comprises an internal copper core and an external plating, and
the internal copper core comprises a triangular portion located above and a rectangular portion located below.

3. The profiled solder ribbon according to claim 2, wherein the top corner of the triangular portion is an arc with a radian of π/36 to 5π/9.

4. The profiled solder ribbon according to claim 2, wherein
two side surfaces of the triangular portion are planes, and the external plating comprises a first plating disposed outside the two side surfaces of the triangular portion; and the reflectivity of the first plating is 70-100%.

5. The profiled solder ribbon according to claim 4, wherein
a material of the first plating is selected from one or more of aluminum, aluminum alloy, silver, silver alloy, tin, and lead.

6. The profiled solder ribbon according to claim 4, wherein the thickness of the first plating is 1-6 μm.

7. The profiled solder ribbon according to claim 2, wherein
two side surfaces of the triangular portion of the internal copper core are formed into concave surfaces inwards; and the external plating comprises a second plating disposed outside the concave surfaces and made of tin or tin alloy.

8. The profiled solder ribbon according to claim 7, wherein the thickness of the second plating is 8-15 μm.

9. The profiled solder ribbon according to claim 1, wherein
the rectangle of the profiled segment has the same shape and size as the section of the flat segment, and for the rectangle of the profiled segment and the rectangle of the section of the flat segment, a corner between a bottom and each side is rounded.

10. The profiled solder ribbon according to claim 1, wherein
a height of the first transition segment and a height of the second transition segment gradually decrease from the profiled segment to the flat segment.

11. The profiled solder ribbon according to claim 1, wherein
a section of the first transition segment and a section of the second transition segment are each in a shape formed by an isosceles trapezoid located above and a rectangle located below.
